(19) United States
(12) Patent Application Publication
(10) Pub. No.: US 2010/0055398 A1
(43) Pub. Date: Mar. 4, 2010

(54) Single-Sided Textured Sheet Wafer

(75) Inventors: Guenther Grupp Mueller, Arlington, MA (US); Brian McMullen, Hubbardston, MA (US)

Correspondence Address: Sunstein Kann Murphy & Timbers LLP, 125 SUMMER STREET, BOSTON, MA, 02110-1618, US

(73) Assignee: EVERGREEN SOLAR, INC., Marlborough, MA (US)

(21) Appl. No.: 12/546,942

(22) Filed: Aug. 25, 2009

Related U.S. Application Data
(60) Provisional application No. 61/092,818, filed on Aug. 29, 2008.

(51) Int. Cl. H01L 21/306; B32B 5/00; H01L 21/302

(52) U.S. Cl. 428/141; 156/345.11; 156/345.18; 156/345.21; 438/753; 257/E21.309

(57) ABSTRACT

An apparatus for texturing two-sided wafers has a body capable of containing texturing chemistry (i.e., not necessarily containing the chemistry at this time), and a transport mechanism for transporting wafers through the texturing chemistry. The transport mechanism is configured to substantially wet no more than one side of wafers, transported through the body, with texturing chemistry.

### PRIORITY

This patent application claims priority from provisional United States patent application No. 61/092,818, filed Aug. 29, 2008 entitled, “SINGLE-SIDED TEXTURED SHEET WAFER,” and naming Guenther Grupp and Brian McMullen as inventors, the disclosure of which is incorporated herein, in its entirety, by reference.

### FIELD OF THE INVENTION

The invention generally relates to silicon wafer processing and, more particularly, the invention relates to texturing silicon sheet wafers.

### BACKGROUND OF THE INVENTION

One of the primary goals of the solar module industry is to achieve “grid-parity,” which generally means that the cost per produced watt of electricity from a solar module is comparable to the cost per produced watt of electricity produced from conventional means (i.e., from the “grid”). In its drive for grid parity, the solar industry strives both to reduce the cost of producing solar modules and improve module energy conversion efficiency.

One widely used technique to improve cell efficiency involves applying a surface texture to the face of a solar cell. To that end, solar cells formed from ribbon crystals, for example, typically are fabricated by immersing an entire ribbon crystal wafer within an acid chemistry. Undesirably, this process unnecessarily textures both sides of the wafer, thus consuming additional acid texturing chemistry.

Moreover, subsequent processes may require one side of the wafer to be smooth. For example, some subsequent processes passivate the backside of the wafer with an oxide. Such passivation processes known to the inventors, however, require a smooth surface, thus further complicating solar cell fabrication.

### SUMMARY OF THE INVENTION

In accordance with one embodiment of the invention, a silicon sheet wafer has a silicon body with first and second sides. The silicon of the silicon body on the first side has a first roughness value while, in a corresponding manner, the silicon of the silicon body on the second side has a second roughness value. The second roughness value is greater than the first roughness value. More specifically, the silicon of the silicon body on the first side is substantially smooth, while the silicon of the silicon body on the second side is textured.

For example, the second roughness value may have a RMS value of greater than about 0.3 microns. In that case, the first side may be substantially smooth while the second side is textured. Moreover, the wafer may have a plurality of strings extending along its length (e.g., it may be a string ribbon wafer). In addition or alternatively, the wafer also may have a material on both the first side and the second side. This material has a greater surface tension than that of the silicon forming the wafer.

In accordance with another embodiment of the invention, an apparatus for texturing two-sided wafers has a body capable of containing texturing chemistry (i.e., not necessarily containing the chemistry at this time), and a transport mechanism for transporting wafers through the texturing chemistry. The transport mechanism is configured to substantially wet no more than one side of wafers, transported through the body, with texturing chemistry.

The transport mechanism illustratively is configured to substantially completely cover no more than one side of a wafer (transported through the body) with the texturing chemistry. For example, the transport mechanism may be configured to substantially prevent the texturing chemistry from contacting both sides of a wafer transported through the body (e.g., it is configured to permit the chemistry to contact only one side in a substantial manner).

Among other things, the transport mechanism may at least have a plurality of rollers. In that case, the body may be configured to control the level of texturing chemistry not to extend above the rollers, or to permit it to extend above the rollers. To control the chemistry level, the body may have a fluid outlet and a fluid inlet, which is in fluid communication with a pump. Alternatively, the transport mechanism may have a plurality of channels in fluid communication with a pump. To facilitate wafer transport, the body in the latter embodiment may be oriented at an angle.

During use, the apparatus also includes texturing chemistry (e.g., a combination of three acids) and a plurality of wafers within the body.

In accordance with other embodiments, an apparatus for texturing two-sided wafers has a body, a transport mechanism for transporting wafers through the body, and a spray mechanism for spraying no more than one side of wafers with a texturing chemistry within the body.

In accordance with still other embodiments, a method of texturing a two-sided silicon sheet wafer provides a texturing chemistry, and transports the wafer through the texturing chemistry in a manner that wets no more than one side of the wafer with the texturing chemistry.

Illustrative embodiments transport the wafer so that the wafer forms a meniscus with the texturing chemistry. Some techniques may apply a material to the wafer having a higher surface tension than that of the wafer. This material should facilitate formation of the meniscus.

In accordance with yet other embodiments, a method of texturing a two-sided silicon sheet wafer provides a texturing chemistry and transports the wafer through the texturing chemistry to substantially completely wet a first side of the wafer with the texturing chemistry. Moreover, the method also transports the wafer through the texturing chemistry to no more than negligibly wet a second side of the wafer.

In other embodiments, a method of texturing a sheet wafer provides a texturing chemistry in a texturing region, and transports a two-sided sheet wafer through the texturing region. The texturing chemistry wets the wafer when in the texturing region so that no more than one of the two sides of the wafer is wetted with the texturing chemistry.

Some other embodiments have an apparatus for texturing wafers with a specialized texturing region. Specifically, in some embodiments using this region, the apparatus has a body with a texturing region configured to apply texturing chemistry to a sheet wafer, and a transport mechanism for transporting sheet wafers through the texturing region. The transport mechanism and texturing region are configured to transport the sheet wafers through the texturing region to substantially wet with texturing chemistry the first side of sheet wafers passing therethrough. In a corresponding manner, the transport mechanism and texturing region are configured not to wet with the texturing chemistry the second side of sheet wafers passing therethrough.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically shows the front surface of a sheet wafer textured in accordance with illustrative embodiments of the invention.

FIG. 1B schematically shows the back surface of a sheet wafer textured in accordance with illustrative embodiments of the invention.

FIG. 2 schematically shows a cross-sectional view of in-use texturing equipment configured in accordance with illustrative embodiments of the invention.

FIG. 3 schematically shows an enlarged, cross-sectional view of a portion of the texturing equipment of FIG. 2.

FIG. 4 shows a process of texturing a sheet wafer in accordance with illustrative embodiments of the invention.

FIG. 5 schematically shows a cross-sectional view of in-use texturing equipment configured in accordance with alternative embodiments of the invention.

FIG. 6 schematically shows a cross-sectional view of in-use texturing equipment configured in accordance with other embodiments of the invention.

FIG. 7 schematically shows additional details of the texturing equipment shown in FIG. 6 in accordance with various embodiments of the invention.

FIG. 8 schematically shows different views of the texturing equipment of FIG. 7.

### DESCRIPTION OF ILLUSTRATIVE EMBODIMENTS

In illustrative embodiments, specially configured texturing equipment textures no more than a single side of a sheet wafer (e.g., a wafer formed from a string ribbon crystal). Accordingly, one side of the sheet wafer is substantially smooth while the other side is textured. Details of illustrative embodiments are discussed below.

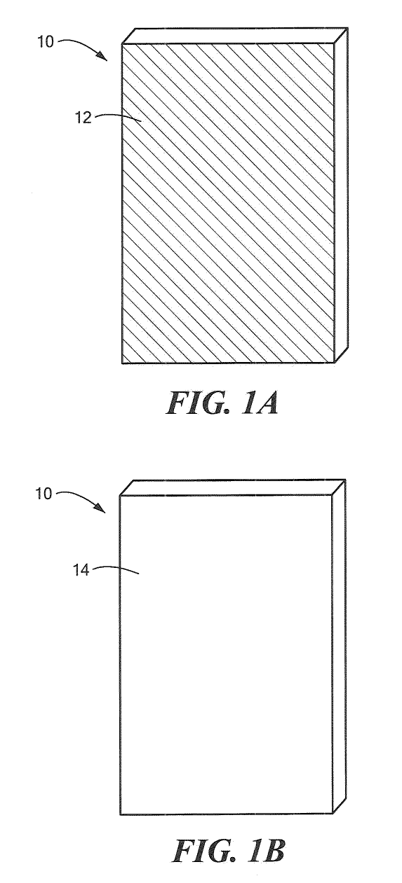

FIGS. 1A and 1B schematically show opposite sides of a single sheet wafer (“wafer 10”) configured in accordance with illustrative embodiments of the invention. Among other things, the sheet wafer 10 may be formed from a string ribbon crystal, such as those described in various patents naming Emanuel M. Sachs as the inventor. For example, U.S. Pat. No. 4,661,200 shows a string ribbon crystal and teaches a method of forming a string ribbon crystal.

More generally, a sheet wafer is formed from a process that grows the (generally planar) wafer directly from molten material, such as the process for forming ribbon crystals. This is in contrast to conventional wafers formed from Czochralski crystal pulling techniques, which cut generally planar wafers from a large ingot of frozen wafer material. Specifically, a sheet wafer forms directly from a melt, while a wafer formed using the Czochralski techniques requires another step to make it generally planar; namely, a sawing step. In fact, this sawing step can serve as the basis for a texture on cells formed from Czochralski wafers, thus avoiding significant texturing steps for the purposes described herein for photovoltaics. Sheet wafers often do not have this benefit—instead, they often are smooth and thus, require this extra texturing step. As noted above, prior art processes known to the inventors texture both sides of a sheet wafer.

The wafer 10 shown in FIGS. 1A and 1B is generally planar with a generally rectangular shape and a relatively large surface area on its front and back surfaces 12 and 14. FIG. 1A shows the front surface, while FIG. 1B shows the back surface 14. By way of example, the wafer 10 may have a width of about 3 inches, and a length of 6 inches. As known by those skilled in the art, the length can vary significantly depending upon the application, while the width also can vary depending upon the separation of its two strings. Accordingly, discussion of specific lengths and widths are illustrative and not intended to limit various embodiments the invention.

In addition, the thickness of the wafer 10 varies and is very thin relative to its length and width dimensions. Specifically, the wafer may have a thickness ranging from about 190 microns to about 320 microns across its width. Despite this range, the wafer 10 may be considered to have an average thickness across its length and/or width. The wafer 10 may be formed from any of a wide variety of materials and crystal types, such as multi-crystalline, single crystalline, polycrystalline, microcrystalline or semi-crystalline materials. For example, the wafer 10 may be formed from polysilicon.

The wafer 10 shown in FIGS. 1A and 1B may be used for a number of applications, such as solar cells. It nevertheless should be noted that the wafer 10 may be use in other applications and thus, is not limited to use in solar cells. In a similar manner, discussion of a string ribbon wafer is for illustrative purposes only and not intended to limit a number of other embodiments.

As shown in FIGS. 1A and 1B, the wafer 10 has a textured front surface 12 and, conversely, a substantially smooth backside surface 14. When used as a solar cell, only the front surface 12 receives light. The back surface 14 illustratively is covered with a layer having a passivation portion, such as an oxide, and conductive contacts (e.g., formed from aluminum).

Unlike prior art sheet wafer texturing processes, illustrative embodiments texture one side of the wafer 10 only (e.g., the front surface 12, as shown in FIGS. 1A and 1B). Doing so, however, presented a significant technical challenge. The inventors overcame these challenges by developing texturing equipment and processes that, the substantial majority of the time (i.e., for the substantial majority of wafers the equipment processes), prevent non-negligible amounts of texturing chemistry from contacting/wetting the back surface 14 of the wafer 10.

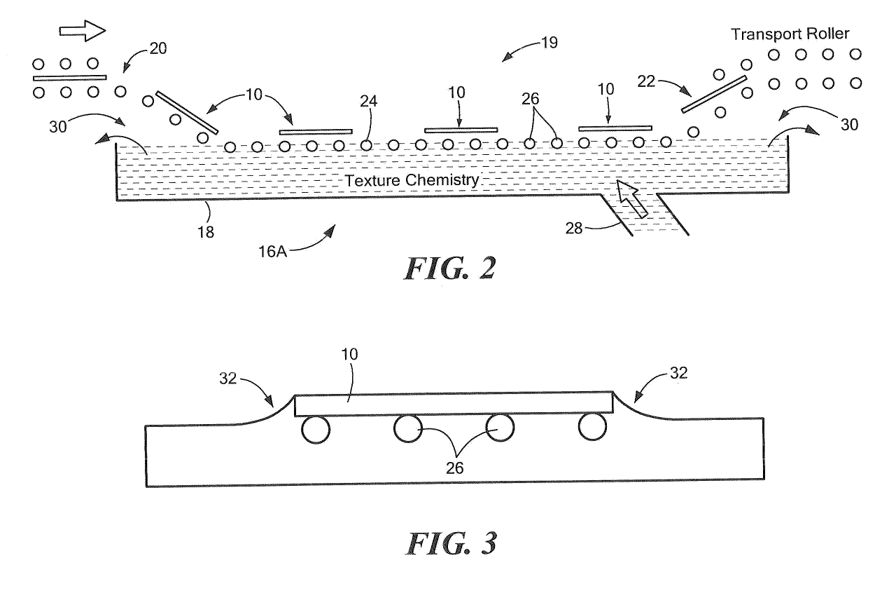

To that end, FIG. 2 schematically shows a cross-sectional view of wafer texturing equipment 16A configured in accordance with illustrative embodiments of the invention. In this embodiment, a plurality of wafers 10 sequentially enter and exit a texturing bath 18 (i.e., a container with our without fluid—in this embodiment a texturing region 19) containing texturing chemistry. More specifically, the texturing equipment 16A of this embodiment has the noted texturing bath 18 with a wafer inlet 20 for receiving the wafers 10, and a wafer outlet 22 for delivering the textured wafers to subsequently positioned equipment, such as rinsing devices (not shown). The texturing equipment 16A also has a temperature controller, such as a chiller (not shown), to control the temperature of the texturing chemistry.

The texturing equipment 16A of this embodiment also has a transport mechanism 24 for transporting the wafers 10 from the wafer inlet 20, through the texturing chemistry, and through the wafer outlet 22. In illustrative embodiments, the transport mechanism 24 includes a plurality of mechanized rollers 26 that slowly move the wafers 10 through the texturing chemistry. The rollers 26 thus are configured to rotate at a speed adequate for appropriately texturing the wafers 10. Moreover, the rollers 26 preferably do not move the wafers 10 in a manner that creates an unfavorable turbulence in the texturing chemistry.

Some embodiments are capable of processing wafers 10 in parallel. For example, such embodiments may have multiple adjacent transport mechanisms 24 that each serially texture wafers 10.

The texturing chemistry may be selected based upon a number of factors, such as 1) the material forming the wafer 10, 2) the size of the wafer 10, 3) the depth of the texturing bath 18, and 4) the ultimate desired characteristics of the texture on the top surface of the wafer 10. For example, the inventors have tested various embodiments by using a combination of sulfuric acid, hydrofluoric acid, and nitric acid to texture a polysilicon ribbon wafer. When using this combination of acids, the sulfuric acid creates bubbles on the front surface 12 of the wafer 10 while the nitric acid creates a thin silicon oxide on the front surface 12 of the wafer 10. The hydrofluoric acid erodes the thin silicon oxide around each bubble, thus forming “pockmarks” (i.e., generally rounded indents) on the front silicon surface 12 of the wafer 10.

In one example, the texturing chemistry is (all percentages approximate) 5% HF (hydrofluoric acid), 5% HNO3 (nitric acid), 90% H2SO4 (sulfuric acid). Illustrative embodiments may have a range of those acids—from 40% hydrofluoric acid, 40% nitric acid 20% sulfuric acid at one end of the spectrum, to 1% hydrofluoric acid, 1% nitric acid, and 98% sulfuric acid on another end of the spectrum. As noted above, one desirable composition has a higher sulfuric acid concentration, 80-95%, with attendant lower hydrofluoric acid and nitric acid. Of course, the hydrofluoric acid and nitric acid can be in ratios other than the noted 1:1 ratio, although such a ratio is preferred for these two acids.

Certain combinations of texturing chemistries and wafer materials undesirably can create chemical reactions that increase the temperature of the texturing chemistry. The above noted chiller thus controls these temperature increases. In addition, chemical reactions also can produce byproducts, such as water, that undesirably may impede the texturing process. For example, the combination of acids described above creates water when reacting with polysilicon. Increasing the water within the texturing chemistry undesirably can cause the bubbles formed on the front surface 12 of the wafer 10 to increase in size. In fact, this increase in size can be greater than that recommended for creating an appropriate texture.

Accordingly, to counteract the problems associated with heat and excessive water in the texturing chemistry, the texturing bath 18 has a pump inlet 28 for pumping fresh texturing chemistry into the bath 18, and a plurality of overflow outlets 30 for expelling texturing chemistry from the bath 18. The expelled texturing chemistry may be processed (e.g., chilled) for reuse in the system, or simply discarded.

To ensure appropriate texturing, however, care must be taken to minimize any turbulence within the texturing chemistry. Accordingly, the pump (not shown) must be calibrated to pump the texturing chemistry at a rate that minimizes turbulence. Considerations to take into account include the viscosity of the texturing chemistry, physical and material characteristics of the sheet wafer, and geometry of the overall equipment 16A (e.g., the shape and size of the texturing bath 18 and its various ports). The pump thus may be calibrated by conventional testing methods to determine appropriate flow rate. For example, after roughly calculating an appropriate flow rate, an operator simply may conduct a number of test runs to determine appropriate flow rate.

During operation, the pump maintains the texturing chemistry at a height that does not wet the back surface 14 of the wafer 10. For example, when no wafers 10 are in the bath 18, the texturing chemistry may be at a height that is approximately equal to the top of the rollers 26, or slightly above the top of the rollers 26. FIG. 3 schematically shows an example of one wafer 10 within the texturing bath 18 of FIG. 2. As shown, the wafer 10 forms a small meniscus 32 with the texturing chemistry. This meniscus 32 extends along the side of the wafer 10, but does not wet the back surface 14 of the wafer 10. The viscosity of the sulfuric acid aids in maintaining the meniscus 32, which is an important part of substantially preventing wetting of the back surface 14.

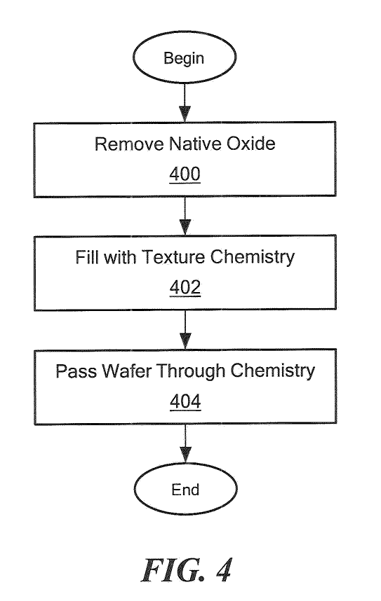

FIG. 4 shows a simplified process of texturing the wafer 10 of FIG. 1 in accordance with illustrative embodiments of the invention. It should be noted that this method is a simplified summary of the overall process of texturing the wafer 10 and thus, does not include a number of other steps that may be included. Moreover, some steps may be performed in a different order or, in some instances, omitted. It also should be noted that discussion of this method of FIG. 4 is not intended to be construed as the only method of texturing the wafer 10 in accord with various embodiments. Those skilled in the art thus may modify the process as necessary.

The process begins at step 400, which removes a native oxide formed on the surface of the wafer 10. Specifically, as known by those skilled in the art, a ribbon crystal wafer undesirably can form a thin native oxide as it is drawn from a crucible of molten silicon. Accordingly, to remove this native oxide, illustrative embodiments perform a preliminary hydrofluoric acid etch on both sides of the wafer 10. This hydrofluoric etch favorably increases the hydrophobicity of the wafer 10. This increased hydrophobicity in turn more effectively forms the meniscus 32 shown in FIG. 3 (when in the texturing chemistry), thus minimizing the likelihood that the texturing chemistry will wet the back surface 14.

Before, while, or after executing step 400, the process fills the empty bath 18 with an appropriate texturing chemistry (step 402). In addition, the process also prepares the remainder of the texturing equipment 16A for operation. The process concludes by passing wafers 10 through the texturing region 19/texturing chemistry (step 404).

The wafer 10 then moves to post-texturing processing areas, such as a water rinse area (not shown). Before moving to such an area, illustrative embodiments direct positive air pressure toward the wafer 10 to remove texturing chemistry residue from its front surface 12. For example, a conventional air knife (not shown) may blow air at an angle toward the front surface 12 of the wafer 10. The air knife should be configured not to create additional turbulence in the texturing chemistry. Accordingly, some embodiments may have a second air knife blowing in a generally opposite direction to that of the first air knife to counteract its potentially turbulent effects. The opposite air flow of the second air knife also may prevent the first air knife from blowing texturing chemistry onto the back surface 14 of the wafer 10.

Illustrative embodiments may form the front surface 12 to have a root mean squared roughness (hereinafter “RMS”) value of greater than about 0.3 microns. For example, during testing, the inventors used a white-light interferometer to measure RMS of the two surfaces 12 and 14. The front (textured) surface 12 had RMS values of between about 0.3 microns and about 0.7 microns. The back (untextured/smooth) surface 14 had RMS values of between about 0.006 microns and about 0.03 microns. Of course, these RMS values are illustrative and should not limit various embodiments of the invention.

More specifically, as known by those in the art, characterization of surface topography is challenging because surfaces generally have a distribution of asperities, ridges, pits and valleys, all of which may have variable shapes and dimensions. For this reason, the surface irregularities that form the surface texture may generally be characterized by some type of average. One common representation of surface roughness, RMS, averages the height deviation of N observed asperities Zi, from the mean, Z-bar:

$$RMS = {[ {\sum }_{i = 1}^{N} {( {Z}_{i} - Z \text{-} bar )}^{2} / ( N - 1 ) ]}^{0.5}$$

Since RMS is an averaged value, surfaces that have different irregularities may have the same RMS. Furthermore, RMS is scale dependent, which means that an RMS value based on one type of measurement (e.g., using a profilometer measurement) may differ from one measured with another type of technique (e.g., using an atomic force microscope).

Accordingly, illustrative embodiments substantially completely contact the front surface 12 of the wafer 10 with texturing chemistry, but substantially prevent non-negligible amounts of texturing chemistry from contacting/wetting the back surface 14. This contact should produce a textured surface having the desired qualities for a given application. In addition, for a sheet wafer, such as one formed from a ribbon crystal, this process should maintain a substantially smooth back surface 14. Accordingly, processes requiring a smooth surface, such as a back-side passivation step with an oxide, should be simpler to perform and thus, less expensive. This eliminates the need for smoothing the back surface 14 to perform this passivation step.

Various embodiments thus produce a desired sheet wafer 10 that requires less processing for subsequent steps, such as passivation. This desired result is achieved while expending substantially less texturing chemistry than prior art processes that texture both surfaces. As a result, overall part cost should decrease when compared to prior art processes (e.g., the cost of forming a solar cell should decrease).

The embodiments described above are several of a variety of different embodiments that can texture a single side of the wafer 10. The remaining figures show additional examples for implementing illustrative embodiments of the invention.

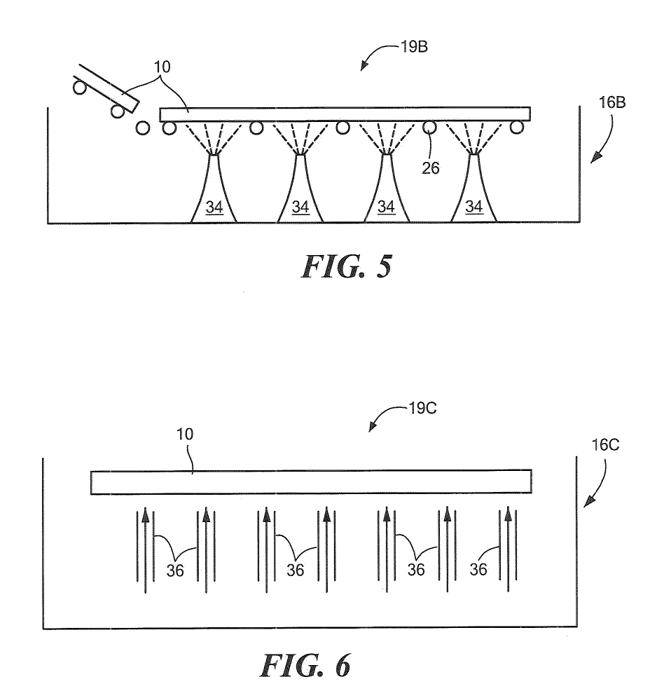

To that end, FIG. 5 schematically shows a cross-sectional view of texturing equipment 16B with a texturing region 19B that sprays the texturing chemistry on one side of the wafer 10. In a manner similar to the embodiment shown in FIG. 2, this embodiment also may use motorized rollers 26 that urge the wafers 10 through the texturing chemistry sprayed in the texturing region 19B. To that end, this embodiment has a plurality of spray heads 34 that are specially configured to spray only the front surface 12 of the wafer 10. They also should be configured to not spray when they are not beneath one of the wafers 10.

FIG. 6 schematically shows a cross-sectional view of yet another embodiment for texturing the wafer 10. Unlike the above noted embodiments, the transport mechanism 24 does not have motorized rollers 26 between the wafer inlet 20 and wafer outlet 22. Instead, the texturing equipment 16C has a texturing region 19C with a plurality of fluid jets 36 that deliver the texturing chemistry to the bath 18. The bath 18, however, is tilted at a shallow angle to the horizontal to urge the wafers 10 to float from the wafer inlet 20 to the wafer outlet 22. For example, this angle may be between one and ten degrees, or more specifically, between one and three degrees. This angle thus causes a slight flow of fluid, which flows downstream from the wafer inlet 20 toward the wafer outlet 22.

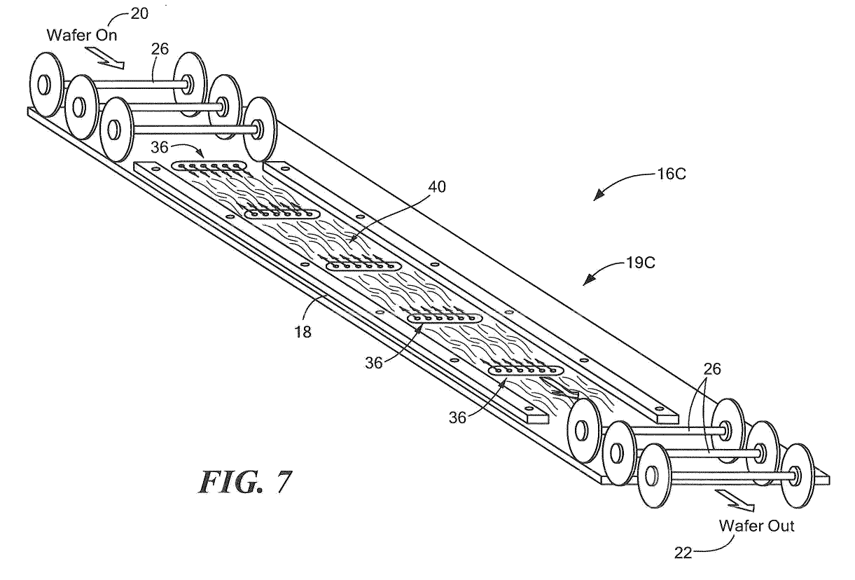

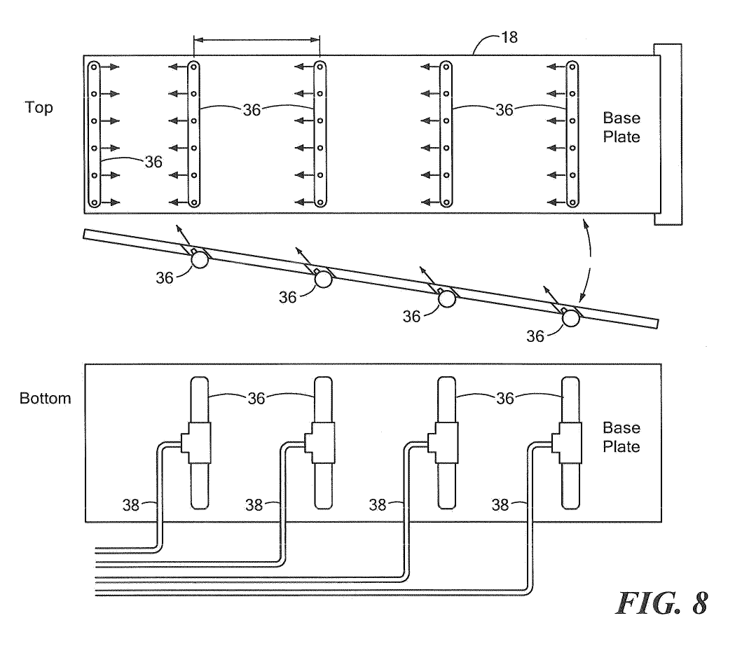

FIGS. 7 and 8 show more details of one implementation of the embodiment shown in FIG. 6. Specifically, this texturing equipment 16C includes a plurality of motorized rollers 26 at the wafer inlet 20, and a corresponding set of rollers 26 at the wafer outlet 22. As noted above, unlike the prior discussed embodiments, this embodiment has no rollers 26 between the wafer inlet 20 and wafer outlet 22. Wafers 10 therefore enter the bath 18 through the wafer inlet 20 and float downstream toward the wafer outlet 22.

To control fluid flow, fluid channel has a plurality of fluid jets 36 that pump texturing chemistry or other fluid into the bath 18. The fluid jets 36 preferably pump the texturing chemistry in a predefined manner to reduce the traveling speed of the wafers 10 and ensure an appropriate chemistry level within the bath 18. The arrows in FIGS. 7 and 8 show the general directions of one embodiment. As shown, some of the jets 36 create a force in a direction that generally opposes the downstream flow of the texturing chemistry toward the wafer outlet 22. In illustrative embodiments, this force does not necessarily cause the texturing chemistry to move appreciably upstream toward the inlet 20. It does, however, help control the rate of flow of the texturing chemistry toward the outlet 22. For example, the force may slow the rate of flow of texturing chemistry toward the outlet.

To those ends, the jets 36 may force texturing fluid from their respective outlets in a manner that has a component/vector generally in an upstream direction. Accordingly, the fluid may exit the jets 36 in a directly upstream direction, or in a direction that is angled almost up to generally orthogonal (i.e., up to but not including about 90 degrees) to the flow of the texturing chemistry in the bath 18. Thus, a jet 36 forcing fluid ninety degrees or greater relative to the fluid flow is not considered to force fluid in a generally upstream direction.

Among other ways, the jets 36 may be pointed in an upstream direction, have a nozzle that provides that function, or both. Also, as noted above, although it forces fluid in a generally upstream direction, a given jet does not necessarily force appreciable amounts of texturing chemistry upstream. Instead, the jets 36 act to control fluid flow to assist in transporting wafers toward the outlet 22.

Of course, some embodiments may have additional fluid jets 36 and/or pump the texturing chemistry in a different manner. For example, more than one jet 36 may pump texturing chemistry in a downstream direction. Among other things, FIG. 8 schematically shows a bottom view of the fluid bath 18 and fluid lines 38 for delivering texturing chemistry to the pump heads.

Moreover, to provide further flow control, some embodiments can have one or more jets 36 that eject fluid in a generally downstream direction. Alternative embodiments can have both types of jets 36—one or more ejecting fluid in a generally upstream direction and one or more ejecting fluid in a generally downstream direction.

The bottom and/or side surface of the bath 18 may be specially textured to further control the flow of the texturing chemistry. For example, FIG. 7 schematically shows a plurality of grooves 40 that are generally parallel to the longitudinal axis of the bath 18. Alternative embodiments may provide a scalloped interior bath surface or other specially configured surface.

Although the above discussion discloses various exemplary embodiments of the invention, it should be apparent that those skilled in the art can make various modifications that will achieve some of the advantages of the invention without departing from the true scope of the invention.

What is claimed is:

1. A method of texturing a sheet wafer, the method comprising:
providing a texturing chemistry in a texturing region; and
transporting a two-sided sheet wafer through the texturing region,
the texturing chemistry wetting the wafer when in the texturing region, the texturing region wetting no more than one of the two sides of the wafer with the texturing chemistry.

2. The method as defined by claim 1 wherein a first side of the wafer is substantially free of the texturing chemistry when in the texturing region, further wherein the texturing region comprises a bath of texturing chemistry, transporting comprising causing the wafer to form a meniscus with the texturing chemistry in the bath, the meniscus acting as an effective barrier to substantially prevent the bath from wetting the first side of the wafer.

3. The method as defined by claim 2 further comprising applying a material to the wafer, the material having a higher surface tension than that of the wafer.

4. The method as defined by claim 1 wherein the wafer comprises a string ribbon wafer.

5. The method as defined by claim 1 wherein the texturing chemistry comprises at least three acids.

6. The method as defined by claim 5 wherein one of the three acids comprises sulfuric acid, the other two acids each having a lower concentration in the texturing chemistry than the sulfuric acid.

7. The method as defined by claim 5 wherein one of the three acids comprises sulfuric acid, the other acids together forming between about 2 and 80 percent of the texturing acid, the other two acids each having a lower viscosity than that of the sulfuric acid.

8. The method as defined by claim 7 wherein the other two acids comprise nitric acid and hydrofluoric acid.

9. The method as defined by claim 1 wherein transporting comprises directing the wafer through a bath of the texturing chemistry along a plurality of rollers.

10. The method as defined by claim 9 further comprising controlling the level of the texturing chemistry to be no higher than the rollers.

11. The method as defined by claim 9 further comprising controlling the level of the texturing chemistry to be higher than the rollers.

12. The method as defined by claim 1 wherein the texturing region has a plurality of spray devices, spraying comprising spraying the texturing chemistry on one side of the wafer.

13. The method as defined by claim 1 wherein the texturing region has a wafer transport mechanism that comprises a bath a plurality of channels forcing fluid toward the wafer.

14. The method as defined by claim 13 wherein transporting comprises moving the wafer in a downstream direction in the bath, the texturing chemistry moving downstream, the plurality of channels forcing fluid from the channels generally against the downstream flow of the texturing chemistry.

15. The method as defined by claim 1 further comprising transporting a plurality of additional wafers through the texturing region in a manner that wets no more than one side of the additional wafers with the texturing chemistry.

16. The method as defined by claim 1 wherein transporting comprises:
transporting the wafer through the texturing region to substantially completely wet a first side of the wafer with the texturing chemistry; and
transporting the wafer through the texturing region to no more than negligibly wet a second side of the wafer.

17. The method as defined by claim 16 wherein the second side of the wafer is substantially free of the texturing chemistry.

18. A silicon sheet wafer comprising:
a silicon body having first and second sides,
the silicon of the silicon body on the first side having a first roughness value,
the silicon of the silicon body on the second side having a second roughness value,
the second roughness value being greater than the first roughness value, the silicon of the silicon body on the first side being substantially smooth, the silicon of the silicon body on the second side being textured.

19. The silicon sheet wafer as defined by claim 18 wherein the second roughness value has a RMS value of greater than or equal to about 0.3 nanometers, the first roughness value having a RMS value of less than or equal to about 0.03 microns.

20. The silicon sheet wafer as defined by claim 18 wherein the silicon sheet wafer comprises a string ribbon wafer.

21. The silicon sheet wafer as defined by claim 18 further comprising a material on the silicon of both the first side and the second side, the material having a greater surface tension than the silicon forming the wafer.

22. An apparatus for texturing wafers having first and second opposing sides, the apparatus comprising:
a body having a texturing region configured to apply texturing chemistry to a sheet wafer; and
a transport mechanism for transporting sheet wafers through the texturing region,
the transport mechanism and texturing region being configured to transport the sheet wafers through the texturing region to substantially wet with texturing chemistry the first side of sheet wafers passing therethrough,
the transport mechanism and texturing region being configured not to wet with the texturing chemistry the second side of sheet wafers passing therethrough.

23. The apparatus as defined by claim 22 wherein the texturing region is configured to substantially completely cover one side of wafers transported through the texturing region with the texturing chemistry.

24. The apparatus as defined by claim 23 wherein the transport mechanism and texturing region are configured to substantially prevent the texturing chemistry from contacting both sides of a wafer transported through the body.

25. The apparatus as defined by claim 22 wherein the transport mechanism comprises a plurality of rollers.

26. The apparatus as defined by claim 25 wherein the body is configured to control the level of texturing chemistry not to extend above the rollers.

27. The apparatus as defined by claim 25 wherein the body is configured to control the level of texturing chemistry to extend above the rollers.

28. The apparatus as defined by claim 22 wherein the body comprises a fluid outlet and a fluid inlet, the fluid inlet being in fluid communication with a pump for pumping texturing fluid.

29. The apparatus as defined by claim 22 wherein the texturing region comprises a bath containing texturing chemistry.

30. The apparatus as defined by claim 29 wherein the texturing chemistry comprises a combination of sulfuric acid and two other acids.

31. The apparatus as defined by claim 22 further comprising a plurality of sheet wafers traversing through the body.

32. The apparatus as defined by claim 22 wherein the texturing region is oriented at an angle against the horizontal to facilitate wafer transport.

33. The apparatus as defined by claim 32 wherein the angle is between about 1 and 3 degrees.

34. The apparatus as defined by claim 32 wherein the texturing region comprises a bath for containing texturing chemistry flowing in a downstream direction, the transport mechanism further comprising a plurality of channels forcing texturing fluid into bath, the plurality of channels being configured to force texturing fluid into the bath at least partially against the downstream flow.

35. The apparatus as defined by claim 22 further comprising a spray mechanism for spraying no more than one side of wafers with texturing chemistry within the texturing region.
